(19) United States
(12) Patent Application Publication
(10) Pub. No.: US 2021/0404865 A1
(43) Pub. Date: Dec. 30, 2021

(54) Attachment System For Attaching a Sensor to a Substrate, Method of Attaching a Sensor to a Substrate

(71) Applicant: TE Connectivity Norge AS, Blomsterdalen (NO)

(72) Inventors: Harald Aadland, Blomsterdalen (NO); Yngve Boe, Blomsterdalen (NO)

(73) Assignee: TE Connectivity Norge AS, Blomsterdalen (NO)

(21) Appl. No.: 17/360,061

(22) Filed: Jun. 28, 2021

(30) Foreign Application Priority Data
Jun. 26, 2020 (EP) 20182659.1

(51) Int. Cl. G01H 11/08; H01L 41/08; H01L 41/113; H01L 41/313; B32B 7/12; B32B 7/022

(52) U.S. Cl. CPC G01H 11/08; H01L 41/0815; H01L 41/1132; B32B 2457/00; B32B 7/12; B32B 7/022; B32B 2307/536; H01L 41/313

(57) ABSTRACT

An attachment system for attaching a sensor to a substrate includes a first layer of adhesive attaching to the sensor and a second layer of adhesive attaching to the substrate. The first layer is attached to the second layer and the first layer differs from the second layer in at least one of elasticity and hardness.

### CROSS-REFERENCE TO RELATED APPLICATIONS

This application claims the benefit of the filing date under 35 U.S.C. § 119(a)-(d) of European Patent Application No. 20182659, filed on Jun. 26, 2020.

### FIELD OF THE INVENTION

The present invention relates to an attachment system and, more particularly, to an attachment system for attaching a sensor to a substrate and a method of attaching a sensor to a substrate.

### BACKGROUND

A sensor attached to a substrate can develop fractures if subjected to varying temperatures.

### SUMMARY

An attachment system for attaching a sensor to a substrate includes a first layer of adhesive attaching to the sensor and a second layer of adhesive attaching to the substrate. The first layer is attached to the second layer and the first layer differs from the second layer in at least one of elasticity and hardness.

### BRIEF DESCRIPTION OF THE DRAWINGS

The invention will now be described by way of example with reference to the accompanying Figures, of which:

FIG. 1 is a schematic sectional view of an attachment system according to an embodiment;

FIG. 2 is a schematic sectional view of a sensor assembly according to an embodiment;

FIG. 3 is a schematic perspective view of a first step of a method of producing an attachment system;

FIG. 4 is a schematic perspective view of a second step of the method of producing the attachment system;

FIG. 5 is a schematic perspective view of a third step of the method of producing the attachment system;

FIG. 6 is a schematic perspective view of the result of the method according to FIGS. 3, 4, and 5; and

FIG. 7 is a schematic sectional view of the attachment system produced with the method according to FIGS. 3, 4, and 5.

### DETAILED DESCRIPTION OF THE EMBODIMENT(S)

The invention will now be described in greater detail and in an exemplary manner, using embodiments and with reference to the drawings. The described embodiments are only possible configurations in which, however, the individual features as described herein can be provided independently of one another or can be omitted.

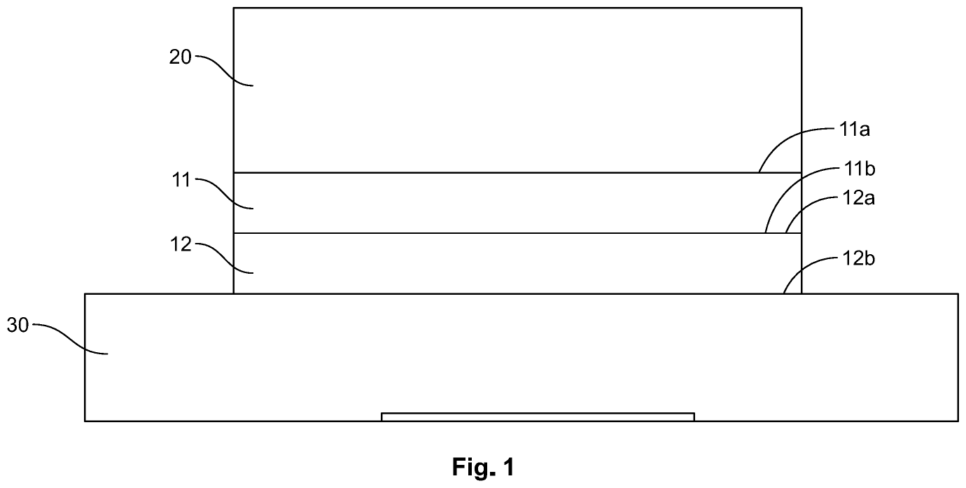

In FIG. 1, a first embodiment of an attachment system 100 is shown connected to a sensor 20 and a substrate 30.

The attachment system 100 for attaching the sensor 20 to the substrate 30 comprises a first layer 11 of adhesive, adapted for attaching the sensor 20, and a second layer 12 of adhesive, adapted for attaching the substrate 30. The first layer 11 is attached to the second layer 12, and the first layer 11 differs from the second layer 12 at least in one of elasticity and hardness. Further, the first layer 11 can differ from the second layer 12 in the curing properties or the curing mechanism. Such an attachment system 100 reduces the risk that the sensor 20 breaks when the temperature changes, for example during a thermal test cycling or during operation. Due to the differences in at least one of the elasticity and the hardness, the attachment system 100 can compensate for differences in the thermal expansion coefficients on the two sides, while still allowing a secure mounting.

In the embodiment shown in FIG. 1, the first layer 11 is rather hard and provides stability, while the second layer 12 is elastic, for example tacky, and takes up the thermal expansion that the substrate 30 exhibits when the temperature is increased. The first layer 11 and the sensor 20 can have a thermal expansion coefficient that is much lower than the thermal expansion coefficient of the substrate 30. The high elasticity of the second layer 12 compensates this difference without leading to a fracture in either of the components; the risk of fracture is minimized or avoided.

If a layer 11, 12 is hard or a solid, it can have a thermal expansion coefficient that is adapted to the thermal expansion coefficient of the material to which it is to be attached. “Adapted to” can in particular mean that the thermal expansion coefficient does not differ by more than 1%, 2%, 3%, 5% or 10% in order to avoid a breaking. In other embodiments, the difference in the thermal expansion coefficients between the layer 11, 12 and the material to which it is attached can differ, if this is for example compensated for with the elasticity or viscosity of one of the layers 11, 12 or the material.

The first layer 11 can differ from the second layer 12 in the elasticity and/or the hardness by at least 3%, at least 5%, at least 10%, at least 20%, or at least 40%. In particular for the elasticity, the difference can be much higher, for example more than 100%, more than 200% or more than 1000%. In an embodiment, the first layer 11 can have a higher hardness and/or a lower elasticity than the second layer 12. This can be useful when the sensor 20 has a low thermal expansion coefficient, while the substrate 30 has a high thermal expansion coefficient.

The first layer 11 can differ from the second layer 12 in the thermal expansion coefficient by at least 3%, at least 5%, at least 10%, at least 20%, or at least 40%. The differences can even be much higher, for example, greater than 100%, 200%, or 500%.

To allow the connection of two different materials, the first layer 11 can differ from the second layer 12 in adhesion properties. The adhesion mechanism for the first layer 11 can be different from the adhesion mechanism for the second layer 12. Possible adhesion mechanisms are mechanical adhesion, for example a positive locking, chemical bonding, physical bonding, van-der-Waals-bonding, electrostatic bonding or diffusive bonding.

Moreover, the first layer 11 can differ from the second layer 12 in curing properties. A curing mechanism for the first layer 11 can be different from a curing mechanism for the second layer 12. For example, one layer, in particular the second layer 12, can have a compression curing mechanism, while the other layer could have an optic, accelerator, heat, or anaerobe curing mechanism.

In order to keep the forces low, when thermal expansion takes place, at least one of the first layer 11 and the second layer 12 can be viscous or viscoelastic. In the embodiment shown in FIG. 1, for example, the second layer 12 is viscoelastic. The viscous part of the viscoelastic response does not result in a force and thus does not put any stress on the attached materials.

In an embodiment, at least one of the first layer 11 and the second layer 12 is flexible. This can facilitate the adaptation to the material to which the layer 11, 12 is attached. In the example of FIG. 1, the second layer 12 is flexible, in order to adapt to a substrate 30 that has, for example, a higher thermal expansion coefficient. The other one of the first layer 11 and the second layer 12 can be stiff. This can help to provide a mechanical stability to the attachment system 100. Further, such a stiff material can for example be better suitable for the transmission of signals or be easier to mount.

In an embodiment, the first layer 11 is solid and the second layer 12 is viscos or viscoelastic. This achieves a good compromise between compensation effect and mechanical stability. The adhesive of the viscous second layer 12 can be tacky or sticky, to allow a good attachment while providing the compensation effect. The solid, first layer 11 can be smooth, in particular to be attachable to a smooth surface of the sensor 20. The solid, first layer 11 can be sheet-like. The solid layer can have a constant thickness.

The attachment system 100 is adapted for attaching the sensor 20 to a first side 11a of the first layer 11 that is opposite a second side 11b, where the second layer 12 is attached, as shown in FIG. 1. The first layer 11 is sandwiched between the sensor 20 and the second layer 12. This results in a compact design.

As shown in the embodiment of FIG. 1, the attachment system 100 attaches the substrate 30 to a second side 12b of the second layer 12 that is opposite a first side 12a at which the first layer 11 is attached. The second layer 12 is sandwiched between the first layer 11 and the substrate 30. This also results in a compact design.

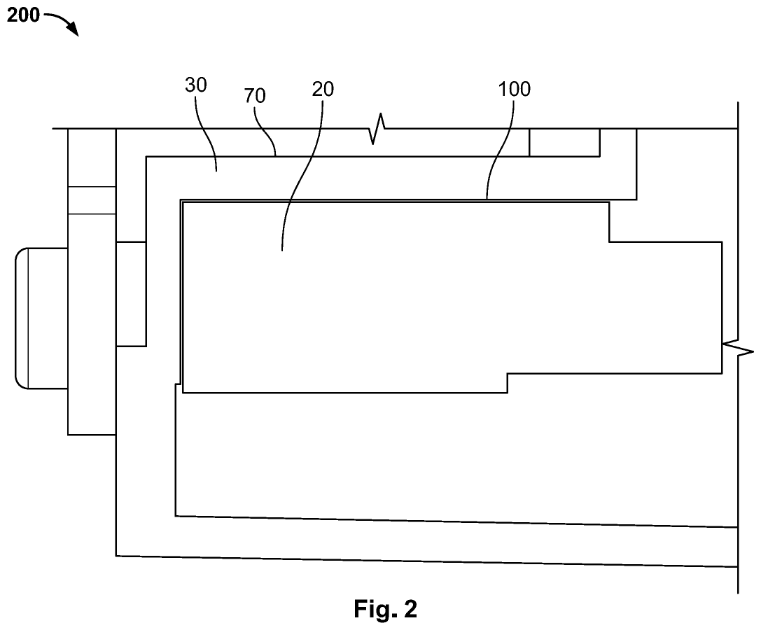

In FIG. 2, a second embodiment of an attachment system 100 is shown in a sensor assembly 200. The sensor assembly 200 comprises a sensor 20 that could be an ultrasound sensor and comprise a piezo element, in an embodiment, and a substrate 30. A signal can leave through a measurement window 70. As the piezo element is brittle and fragile, the use of the attachment system 100 is advantageous. The attachment system 100 shown in FIG. 2 has the same elements and features as the embodiments of the attachment system 100 described in detail with respect to FIG. 1. In addition to the improved thermal performance, the ultrasound sensor 20 can also be decoupled at least partially by the attachment system 100, so that the ultrasound performance is also improved.

In order to allow a repeated attachment and detachment in an easy manner, the sensor assembly 200 can further comprise an intermediate element located between the attachment system 100 and the sensor 20. In an embodiment, the intermediate element is attached to the sensor 20 with a further layer of adhesive. In order to keep the internal stresses low, the further layer of adhesive corresponds in elasticity and/or hardness to the layer 11, 12 of adhesive of the attachment system 100 that is adapted for attaching the sensor 20.

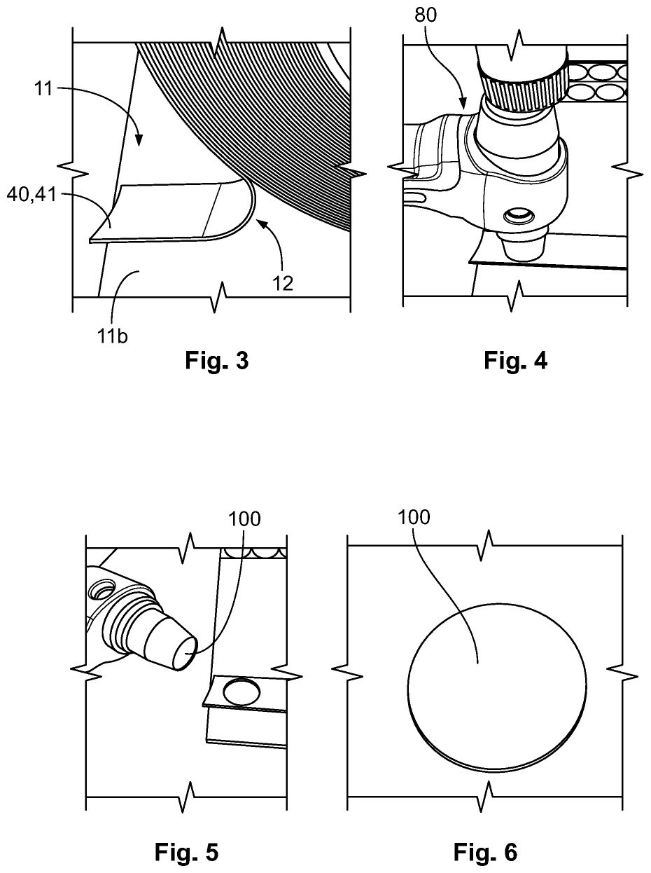

In FIGS. 3 to 7, steps of the production of an attachment system 100 and the resulting attachment system 100 are shown.

In the first step, shown in FIG. 3, the second layer 12 of adhesive, which is supplied from a roll, is joined to the first layer 11 of adhesive in the form of a sheet. The second layer 12 and the first layer 11 are pressed against each other, to achieve a close contact.

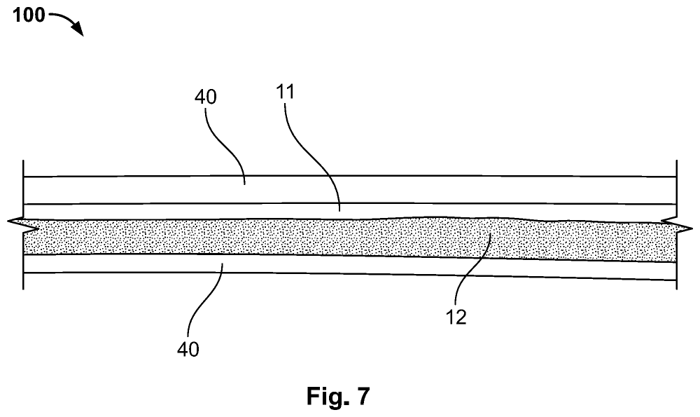

In the second step, shown in FIG. 4, a part of the double layer structure formed by the layers 11, 12 is cut out by using a punching tool 80. The resulting attachment system 100 is then removed from the cavity of the punching tool 80 (FIG. 5) and can be used. In the depicted example, the attachment system 100 has a planar circular shape, as can be seen in FIG. 6. However, other shapes are of course possible. In the cross-sectional view of FIG. 7, the structure of the attachment system 100 can be seen.

FIGS. 3 and 4 also show parts of a method for attaching a sensor 22 to a substrate 30. In particular, these figures show the step of attaching the first layer 11 to the second layer 12, which is performed before the steps of attaching the first layer 11 to the sensor 20 and attaching the second layer 12 to the substrate 30.

In order to allow a simple production, the step of attaching the first layer 11 to the second layer 12 shown in FIG. 3 is performed when at least one of the layers 11, 12 is supported on a carrier structure 40. The carrier structure 40 is in this case a film 41 or a foil. The method can further comprise the step of removing the carrier structure 40 from the first or second layer 11, 12 after the first layer 11 has been attached to the second layer 12. The carrier structure 40 can be removed when the attachment system 100 has been attached to the sensor 20 and/or the substrate 30, in order to use the stabilizing effect of the carrier structure 40 during the step of attaching the attachment system 100 to the sensor 20 or substrate 30.

In a semi-mounted state, the attachment system 100 as produced by the steps shown in FIGS. 3 to 6 can further comprise the sensor 20. Such an attachment system 100 can then be mounted to further elements, in particular to the substrate 30. The sensor 20 can in particular be attached to the layer with higher hardness and/or lower elasticity.

In a different semi-mounted state, the attachment system 100 as produced by the steps shown in FIGS. 3 to 6 can further comprise the substrate 30. Such an attachment system 100 can be mounted to the sensor 20 in a subsequent step. In particular, the substrate 30 can be attached to the layer with the lower hardness and/or the higher elasticity.

The materials for the first layer 11 and/or the second layer 12 are selectively chosen to achieve an attachment system 100 according to the invention. The materials are chosen such that the first layer 11 and the second layer 12 adhere to each other and that each of the layers 11, 12 adheres to the material to which it is to be attached. The thicknesses of the layers 11, 12 can be chosen to achieve a stability with one layer while maintaining the compensation effect of the other layer. The thickness of the layer with higher hardness and/or lower elasticity can be greater by a factor of at least 2, by a factor of at least 3, or by a factor of at least 5 than the thickness of the other layer. In other embodiments, the thickness of the layer with lower hardness and/or higher elasticity can be greater by a factor of at least 2, by a factor of at least 3, or by a factor of at least 5 than the thickness of the other layer.

The elasticity and the hardness of the layers only has to be different in a plane parallel to the layers 11, 12, to allow a compensation of the thermal expansion. In many cases, the elasticity and hardness in a direction perpendicular to the plane is not critical. However, for many materials, the elasticity and the hardness of the layers are isotropic and in particular equal in the directions parallel and perpendicular to the plane.

Further, the difference in the elasticity and/or the hardness should be present in the attached state. In this state, the adhesives are cured.

Elasticity here has to be understood as the ability to respond to a deformation without breaking. Possible concepts for describing this can use Young's modulus for describing the stiffness, the shear modulus for describing the reaction to a shear force, or the bulk modulus for describing the reaction to a compressive strain. Parameters that can be used to describe the elasticity can include in particular Young's modulus up to the yield strength, i.e. the point where the material starts to deform or break under the strain.

Hardness is to be understood as the ability to withstand mechanical forces and to provide mechanical stability. A parameter that can be used for measuring the hardness can be Rockwell, for example HRA or HRB. Standards for the measurements can for example be taken from ISO 6508-1, ISO 6508-2: ISO 6508-3, or ISO 2039-2. Alternative parameters for can be Vickers hardness or Brinell hardness.

The inventive solution could also be used for the attachment of other devices or structures. For example, a first substrate could be attached to a second substrate.

According to the invention, a mechanically stable adhesive is combined with an adhesive that can take up the thermal expansion without being damaged.

What is claimed is:

1. An attachment system for attaching a sensor to a substrate, comprising:
a first layer of adhesive attaching to the sensor; and
a second layer of adhesive attaching to the substrate, the first layer is attached to the second layer and the first layer differs from the second layer in at least one of elasticity and hardness.

2. The attachment system of claim 1, wherein the first layer has a higher hardness.

3. The attachment system of claim 1, wherein the first layer has a lower elasticity.

4. The attachment system of claim 1, wherein the first layer differs from the second layer in an adhesion property.

5. The attachment system of claim 1, wherein the first layer differs from the second layer in a curing property.

6. The attachment system of claim 1, wherein at least one of the first layer and the second layer is viscoelastic.

7. The attachment system of claim 1, wherein one of the first layer and the second layer is solid and the other is viscos or viscoelastic.

8. The attachment system of claim 1, further comprising the sensor attached to the first layer.

9. The attachment system of claim 1, further comprising the substrate attached to the second layer.

10. A sensor assembly, comprising:
a sensor;
a substrate; and
an attachment system including a first layer of adhesive attaching to the sensor and a second layer of adhesive attaching to the substrate, the first layer is attached to the second layer and the first layer differs from the second layer in at least one of elasticity and hardness.

11. The sensor assembly of claim 10, wherein the sensor is a piezo element.

12. The sensor assembly of claim 10, further comprising an intermediate element between the attachment system and the sensor.

13. A method of attaching a sensor to a substrate, comprising:
attaching a first layer of adhesive to the sensor;
attaching a second layer of adhesive to the substrate; and
attaching the first layer of adhesive to the second layer of adhesive, the first layer differs from the second layer in at least one of elasticity and hardness.

14. The method of claim 13, wherein the step of attaching the first layer to the second layer is performed before the step of attaching the first layer to the sensor and before the step of attaching the second layer to the substrate.

15. The method of claim 13, wherein the step of attaching the first layer to the second layer is performed when at least one of the first layer and the second layer is supported on a carrier structure.
